(19) United States
(12) Patent Application Publication
(10) Pub. No.: US 2013/0113555 A1
(43) Pub. Date: May 9, 2013

(54) POWER AMPLIFIER WITH IMPROVED POWER EFFICIENCY

(71) Applicants: Jin Cheol JEONG, Daejeon (KR); In Bok YOM, Daejeon (KR)

(72) Inventors: Jin Cheol JEONG, Daejeon (KR); In Bok YOM, Daejeon (KR)

(73) Assignee: Electronics and Telecommunications Research Institute, Daejeon (KR)

(21) Appl. No.: 13/612,267

(22) Filed: Sep. 12, 2012

(30) Foreign Application Priority Data
Nov. 7, 2011 (KR) 10-2011-0114990

(51) Int. Cl. H03G 99/00

(52) U.S. Cl. 330/127

(57) ABSTRACT

Provided is a power amplifier used in a transmitter of a communication system. The power amplifier may include a power amplifier module to amplify power of a transmitting signal, an energy converter module to receive thermal energy generated by the power amplifier module and to convert the received thermal energy into electric energy, and a direct current (DC)-DC converter module to produce DC power using the electric energy generated by the energy converter module and to supply the produced DC power to the power amplifier module.

### CROSS-REFERENCE TO RELATED APPLICATION

This application claims the priority benefit of Korean Patent Application No. 10-2011-0114990, filed on Nov. 7, 2011, in the Korean Intellectual Property Office, the disclosure of which is incorporated herein by reference.

### BACKGROUND

1. Field of the Invention

Exemplary embodiments relate to a power amplifier with improved power efficiency.

2. Description of the Related Art

A power amplifier or power amp corresponds to an essential component for signal transmission disposed at a front end transmitter of a communication system. The power amplifier is designed in terms of power among the three standards for determining the purpose of use of an amplifier, that is, noise, gain, and power. Power refers to a maximum intensity of an output signal at a front terminal, above 1 decibel-milliwatt (dBm). For a maximum power, parallel arrangement of transistors is widely used to increase power, and in this instance, a great amount of heat generated is involved. Accordingly, a heat emitting design is an important consideration for the power amplifier.

Currently, a foremost issue facing the power amplifier may be improvement in power efficiency. The power amplifier produces a high signal power according to intrinsic characteristics. To produce a high signal power, a much higher direct current (DC) power supply is needed. In this instance, a ratio of signal power to DC power supplied is referred to as power efficiency.

The present invention is to improve power efficiency of a power amplifier through production of DC power rather than through improvement of a circuit. That is, the present invention proposes a method that may convert excess heat of a power amplifier into electric energy using an energy converter module and may convert the electric energy into suitable DC power for use in the power amplifier through a DC-DC converter module, to improve power efficiency of the power amplifier.

### SUMMARY

An aspect of the present invention provides a technique for converting thermal energy generated by a power amplifier for a communication system into electric energy for reuse as a power source of the power amplifier to improve energy efficiency of the power amplifier.

According to an aspect of the present invention, there is provided a power amplifier used in a transmitter of a communication system, the power amplifier including a power amplifier module to amplify power of a transmitting signal, an energy converter module to receive thermal energy generated by the power amplifier module and to convert the received thermal energy into electric energy, and a direct current (DC)-DC converter module electrically connected to the power amplifier module to produce DC power using the electric energy generated by the energy converter module and to supply the produced DC power to the power amplifier module.

The power amplifier may further include a cooling module to cool the energy converter module.

The power amplifier module may be disposed in a first layer, the energy converter module may be disposed in a second layer below the first layer, and the cooling module may be disposed in a third layer below the second layer.

The energy converter module may include a heat generating unit to receive the thermal energy generated by the power amplifier module, a cooling unit to cool the energy converter module, and an energy conversion device to convert the thermal energy generated by a difference in temperature between the heat generating unit and the cooling module into electric energy.

The energy converter module may further include a thermal insulation unit to prevent the thermal energy received in the heat generating unit from flowing into the cooling unit, absent being passed through the energy conversion device.

The heat generating unit may include a first grooved portion to receive the thermal energy generated by the power amplifier module, the cooling unit may include a second grooved portion to emit the thermal energy within the energy converter module to the outside of the energy converter module, and each of the first grooved portion and the second grooved portion may include a groove to increase a cross-sectional area.

The cooling module may include a heat sink to receive the thermal energy emitted from the energy converter module and to dissipate the received thermal energy to an external environment using a plurality of plates having a wide surface area in contact with the external environment, and a fan to cool the external environment by flowing air from the external environment having an increased temperature due to the thermal energy dissipated by the heat sink.

The DC-DC converter module may be electrically connected to the power amplifier module to produce the DC power using the electric energy generated by the energy converter module and electric energy inputted from a separate external power source, and to supply the produced DC power to the power amplifier module.

According to another aspect of the present invention, there is provided a power amplifier used in a transmitter of a communication system, the power amplifier including a power amplifier module to amplify power of a transmitting signal, an energy converter module to receive thermal energy generated by the power amplifier module in a layer below the power amplifier module and to convert the received thermal energy into electric energy, a cooling module to cool the energy converter module in a layer below the energy converter module, and a DC-DC converter module electrically connected to the power amplifier module to produce DC power using the electric energy generated by the energy converter module and to supply the produced DC power to the power amplifier module.

The energy converter module may include a heat generating unit to receive the thermal energy generated by the power amplifier module, a cooling unit to cool the energy converter module, an energy conversion device to convert the thermal energy generated by a difference in temperature between the heat generating unit and the cooling module into electric energy, and a thermal insulation unit to prevent the thermal energy received in the heat generating unit from flowing into the cooling unit, absent being passed through the energy conversion device, the heat generating unit may include a first grooved portion to receive the thermal energy generated by the power amplifier module, the cooling unit may include a second grooved portion to emit the thermal energy within the energy converter module to the outside of the energy converter module, and each of the first grooved portion and the second grooved portion may include a groove to increase a cross-sectional area.

### BRIEF DESCRIPTION OF THE DRAWINGS

These and/or other aspects, features, and advantages of the invention will become apparent and more readily appreciated from the following description of exemplary embodiments, taken in conjunction with the accompanying drawings of which:

FIG. 1 is a block diagram illustrating a power amplifier used in a transmitter of a communication system according to an embodiment of the present invention;

FIG. 2 is a diagram illustrating a configuration of a power amplifier according to an embodiment of the present invention;

FIG. 3 is a diagram illustrating a configuration of an energy converter module according to an embodiment of the present invention; and

FIG. 4 is a diagram illustrating a direct current (DC)-DC converter module according to an embodiment of the present invention.

### DETAILED DESCRIPTION

Reference will now be made in detail to exemplary embodiments of the present invention, examples of which are illustrated in the accompanying drawings, wherein like reference numerals refer to the like elements throughout. Exemplary embodiments are described below to explain the present invention by referring to the figures.

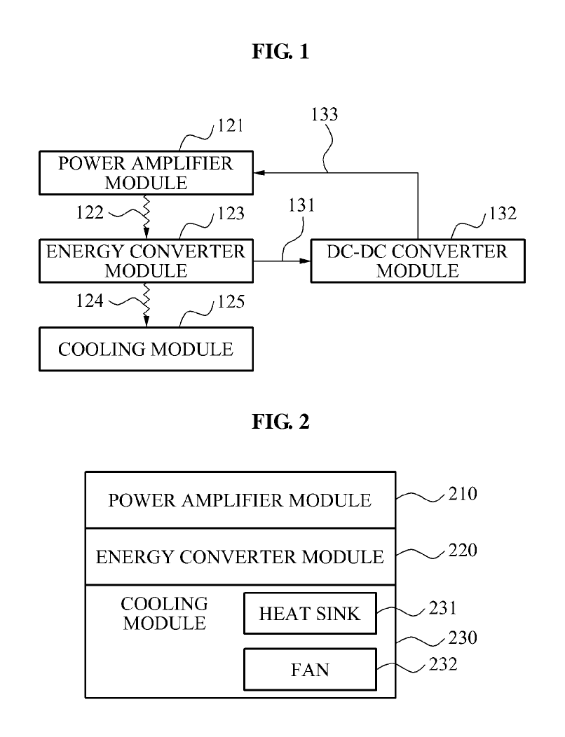

FIG. 1 is a block diagram illustrating a power amplifier used in a transmitter of a communication system according to an embodiment of the present invention.

Prior to providing a description of a configuration of a power amplifier used in a transmitter of a communication system according to an embodiment of the present invention with reference to FIG. 1, a concept of the power amplifier is described in brief.

The power amplifier or power amp is designed in terms of power among the three standards for determining the purpose of use of an amplifier, that is, noise, gain, and power. Power refers to a maximum intensity of an output signal at a front terminal, above 1 decibel-milliwatt (dBm). For a maximum power, parallel arrangement of transistors is widely used to increase power. The maximum power is usually known through 1 dB gain compression point (P1dB). It is difficult to achieve high power and high gain simultaneously. Accordingly, the power amplifier often needs a driving amplifier at a front end for gain compensation.

Since high power involves generation of a great amount of heat, a heat emitting design is an important consideration in designing the power amplifier. For the same reason, power efficiency is another important consideration in designing the power amplifier. The power efficiency may be classified into A, B, AB, and F grades based on linearity and efficiency.

A basic principle of signal amplification is supported by a principle of transistor amplification, and is magnified duplication and output of an input signal. This principle is the same as a bipolar junction transistor (BJT) and a field-effect transistor (FET), but a difference is present in that the BJT uses a current and the FET uses a voltage, to control signal amplification.

In this case, an energy source of signal amplification is a direct current (DC) power source. That is, an input signal is duplicated and magnified to generate an output signal, based on a DC power source applied to an input and an output, wherein the output signal is significantly larger than the input signal and is keeping shape of the input signal.

Referring to FIG. 1, the power amplifier used in the transmitter of the communication system according to an embodiment of the present invention may include a power amplifier module 121 to amplify power of a transmitting signal.

The power amplifier module 121 may execute a basic function of the power amplifier, that is, power amplification. That is, the power amplifier module 121 may be designed in terms of power among the three standards for determining the purpose of use of an amplifier, that is, noise, gain, and power. For a maximum power, the power amplifier module 121 may have a parallel arrangement of transistors to increase power. In this instance, the power amplifier module 121 may generate a great amount of heat according to intrinsic characteristics. The amount of heat generated may be generally dissipated into the air through a heat sink and the like. As described in the foregoing, the power amplifier module 121 needs a DC power source to amplify the power of the transmitting signal. The power amplifier used in the transmitter of the communication system according to an embodiment of the present invention may improve energy efficiency of the power amplifier by converting heat generated by the power amplifier module 121 into electric energy and by using the electric energy as a DC power source necessary for operation of the power amplifier module 121. A detailed description is provided later.

Also, the power amplifier used in the transmitter of the communication system according to an embodiment of the present invention may include an energy converter module 123 to receive the thermal energy generated by the power amplifier module 121 and to convert the received thermal energy into electric energy.

The energy converter module 123 may receive the thermal energy generated by the power amplifier module 121, and may convert the received thermal energy into electric energy for use as a DC power source necessary for operation of the power amplifier module 121.

That is, the power amplifier module 121 may consume a great amount of DC power in producing a high-power signal. In this instance, an amount of DC power much greater than an amount of DC power required to generate the high-power signal may be consumed as heat. This is because power efficiency of the power amplifier module 121 may be very low, for example, in a range between 20 and 30%. In this instance, the power efficiency refers to a ratio of signal power to DC power supplied. When the power efficiency is in a range between 20 and 30%, the remaining 70 to 80% may be consumed as heat. The power amplifier used in the transmitter of the communication system according to an embodiment of the present invention may convert thermal energy generated by the power amplifier into electric energy by passing the consumed thermal energy through the energy converter module 123.

In this case, the energy converter module 123 may use a thermoelectric effect corresponding to an interaction between thermal energy and electric energy. The thermoelectric effect may include the Seebeck effect by which an electromotive force is induced by a difference in temperature, resulting in a current flow, and the Seebeck effect by which a flow of electric current causes a difference in temperature.

The energy converter module 123 may use the Seebeck effect. That is, the energy converter module 123 may use the Seebeck effect by which an electric current flows in a predetermined direction due to a difference in temperature at two junctions of a thermocouple composed of different types of metal wires having a thermoelectric effect. An internal configuration of the energy converter module 123 is described later.

Also, the power amplifier used in the transmitter of the communication system according to an embodiment of the present invention may include a DC-DC converter module 132 electrically connected to the power amplifier module 121 to produce DC power using the electric energy generated by the energy converter module 123 and to supply the produced DC power to the power amplifier module 121.

The electric energy generated by the energy converter module 123 may appear in the form of DC power, and the DC-DC converter module 132 may receive an input of electric energy in the form of DC power. The DC-DC converter module 132 may be generally essential to supply DC power to the power amplifier. The DC-DC converter module 132 may execute a function of converting the DC power input into suitable DC power for use in an internal circuit of the power amplifier. The DC-DC converter module 132 may execute a function of converting the electric energy in the form of DC power generated by the energy converter module 123 into suitable DC power for use in an internal circuit of the power amplifier.

The power amplifier used in the transmitter of the communication system according to an embodiment of the present invention may further include a line to electrically connect the energy converter module 123 to the DC-DC converter module 132, and a line to electrically connect the DC-DC converter module 132 to the power amplifier module 121.

Also, the power amplifier used in the transmitter of the communication system according to an embodiment of the present invention may further include a cooling module 125 to cool the energy converter module 123. In this instance, the cooling module 125 may include a heat sink to receive the thermal energy emitted from the energy converter module 123 and to dissipate the received thermal energy to an external environment using a plurality of plates having a wide surface area in contact with the external environment, and a fan to cool the external environment by flowing air from the external environment having an increased temperature due to the thermal energy dissipated by the heat sink.

Different types of transmitting signals, thermal energy, and DC power may be transmitted between each module of FIG. 1. That is, in 122, the energy converter module 123 may receive thermal energy generated by the power amplifier module 121 during amplification of a transmitting signal. In 124, to maximize the Seebeck effect, the cooling module 125 may cool the energy converter module 123. In 131, the electric energy generated by the energy converter module 123 may be supplied to the DC-DC converter module 132. In 133, the DC-DC converter module 132 may convert the supplied electric energy into suitable DC power for use in an internal circuit of the power amplifier module 121, and may supply the produced DC power to the power amplifier module 121.

FIG. 2 is a diagram illustrating a configuration of the power amplifier according to an embodiment of the present invention.

Referring to FIG. 2, in the power amplifier used in the transmitter of the communication system according to an embodiment of the present invention, the power amplifier module 210 may be disposed in a first layer, the energy converter module 220 may be disposed in a second layer below the first layer, and the cooling module 230 may be disposed in a third layer below the second layer.

In this instance, the cooling module 230 may include a heat sink 231 to receive the thermal energy emitted from the energy converter module 220 and to dissipate the received thermal energy to an external environment using a plurality of plates having a wide surface area in contact with the external environment, and a fan 232 to cool the external environment by flowing air from the external environment having an increased temperature due to the thermal energy dissipated by the heat sink 231.

The power amplifier module, the energy converter module, and the cooling module included in the power amplifier may have various arrangements other than the exemplary arrangement described in the foregoing. For example, the power amplifier module may be disposed in a first layer, the energy converter module may be disposed in a second layer above the first layer, and the cooling module may be disposed in a third layer above the second layer. Also, the power amplifier module may be disposed in a first layer, the energy converter module may be disposed in a second layer at one side of the first layer, and the cooling module may be disposed in a third layer at one side of the second layer. In this instance, the one side of the first layer at which the second layer is disposed and the one side of the second layer at which the third layer is disposed may correspond to a side of the same direction, for example, a right side or a left side.

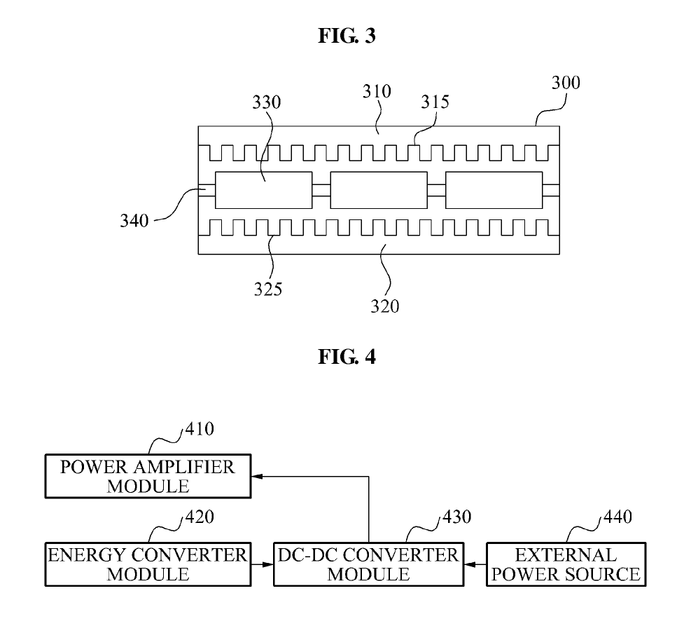

FIG. 3 is a diagram illustrating a configuration of an energy converter module 300 according to an embodiment of the present invention.

Referring to FIG. 3, the energy converter module 300 included in the power amplifier used in the transmitter of the communication system according to an embodiment of the present invention may include a heat generating unit 310 to receive thermal energy generated by the power amplifier module, a cooling unit 320 to cool the energy converter module, and an energy conversion device 330 to convert thermal energy generated by a difference in temperature between the heat generating unit 310 and the cooling module 320 into electric energy.

The energy conversion device 330 may be disposed in a plane to execute an essential function of converting thermal energy into electric energy. The heat generating unit 310 and the cooling module 320 may be disposed at both sides of the energy conversion device 330 to induce an electromotive force by a difference in temperature between both sides. In this instance, the heat generating unit 310 may be attached to the power amplifier module to receive thermal energy generated by the power amplifier module. Also, the cooling unit 320 may be attached to the cooling module to enable the cooling module to cool the cooling unit 320, consequently to cool the energy converter module.

Also, the energy converter module may further include a thermal insulation unit 340 to prevent the thermal energy received in the heat generating unit 310 from flowing into the cooling unit 320 absent being passed through the energy conversion device 330. That is, the thermal insulation unit 340 may be disposed at the remaining area excluding the energy conversion device 330 between the heat generating unit 310 and the cooling unit 320, to minimize an amount of heat failing to pass through the energy conversion device 330. In this instance, the heat insulating unit 340 may include a material having a high thermal insulation effect, for example, glass fiber, asbestos and the like.

In this case, the heat generating unit 310 may include a first grooved portion 315 to receive the thermal energy generated by the power amplifier module, and the cooling unit 320 may include a second grooved portion 325 to emit the thermal energy within the energy converter module to the outside of the energy converter module. In this instance, each of the first grooved portion 315 and the second grooved portion 325 may include a groove to increase a cross-sectional area. The first grooved portion 315 and the second grooved portion 325 may be disposed in a plane to allow the heat generating unit 310 to absorb a great amount of heat and allow the cooling unit 320 to improve cooling performance, respectively.

The energy converter module 300 included in the transmitter of the communication system according to an embodiment of the present invention may further include a DC line to output the DC power produced by the energy conversion device 330.

FIG. 4 is a diagram illustrating a DC-DC converter module 430 according to an embodiment of the present invention.

Referring to FIG. 4, the DC-DC converter module 430 included in the power amplifier used in the transmitter of the communication system according to an embodiment of the present invention may be electrically connected to a power amplifier module 410, and may produce DC power using electric energy generated by an energy converter module 420 and electric energy inputted from a separate external power source 440, and may supply the produced DC power to the power amplifier module 410.

As described in the foregoing, DC power supply is needed to operate the power amplifier module 410. For DC power supply, the DC-DC converter module 430 may produce suitable DC power for use in an internal circuit of the power amplifier module 410. In this instance, the DC-DC converter module 430 may produce suitable DC power for operation of the internal circuit of the power amplifier module 410 using electric energy supplied from the external power source 440 as well as electric energy generated by the energy converter module 420. In this case, the DC-DC converter module 430 may further include a port to receive an input of electric energy supplied from the external power source 440, and the power amplifier according to an embodiment of the present invention may further include a power line for transmission of electric energy between the DC-DC converter module 430 and the external power source 440.

The present invention provides a technique for converting thermal energy generated by a power amplifier for a communication system into electric energy for reuse as a power source of the power amplifier to improve energy efficiency of the power amplifier.

Although a few exemplary embodiments of the present invention have been shown and described, the present invention is not limited to the described exemplary embodiments. Instead, it would be appreciated by those skilled in the art that changes may be made to these exemplary embodiments without departing from the principles and spirit of the invention, the scope of which is defined by the claims and their equivalents.

What is claimed is:

1. A power amplifier used in a transmitter of a communication system, the power amplifier comprising:
a power amplifier module to amplify power of a transmitting signal;
an energy converter module to receive thermal energy generated by the power amplifier module and to convert the received thermal energy into electric energy; and
a direct current (DC)-DC converter module electrically connected to the power amplifier module to produce DC power using the electric energy generated by the energy converter module and to supply the produced DC power to the power amplifier module.

2. The power amplifier of claim 1, further comprising:
a cooling module to cool the energy converter module.

3. The power amplifier of claim 2, wherein the power amplifier module is disposed in a first layer, the energy converter module is disposed in a second layer below the first layer, and the cooling module is disposed in a third layer below the second layer.

4. The power amplifier of claim 1, wherein the energy converter module comprises:
a heat generating unit to receive the thermal energy generated by the power amplifier module;
a cooling unit to cool the energy converter module; and
an energy conversion device to convert the thermal energy generated by a difference in temperature between the heat generating unit and the cooling module into electric energy.

5. The power amplifier of claim 4, wherein the energy converter module further comprises:
a thermal insulation unit to prevent the thermal energy received in the heat generating unit from flowing into the cooling unit, absent being passed through the energy conversion device.

6. The power amplifier of claim 4, wherein the heat generating unit comprises a first grooved portion to receive the thermal energy generated by the power amplifier module,
the cooling unit comprises a second grooved portion to emit the thermal energy within the energy converter module to the outside of the energy converter module, and
each of the first grooved portion and the second grooved portion comprises a groove to increase a cross-sectional area.

7. The power amplifier of claim 2, wherein the cooling module comprises:
a heat sink to receive the thermal energy emitted from the energy converter module and to dissipate the received thermal energy to an external environment using a plurality of plates having a wide surface area in contact with the external environment; and
a fan to cool the external environment by flowing air from the external environment having an increased temperature due to the thermal energy dissipated by the heat sink.

8. The power amplifier of claim 1, wherein the DC-DC converter module is electrically connected to the power amplifier module to produce the DC power using the electric energy generated by the energy converter module and electric energy inputted from a separate external power source, and to supply the produced DC power to the power amplifier module.
